(19) United States
(12) Patent Application Publication
(10) Pub. No.: US 2017/0248487 A1
(43) Pub. Date: Aug. 31, 2017

(54) PRESSURE SENSOR STATE DETECTION METHOD AND SYSTEM

(71) Applicant: Azbil Corporation, Tokyo (JP)

(72) Inventors: Takuya ISHIHARA, Tokyo (JP); Masaru SOEDA, Tokyo (JP); Masashi SEKINE, Tokyo (JP); Hidenobu TOCHIGI, Tokyo (JP)

(73) Assignee: Azbil Corporation, Tokyo (JP)

(21) Appl. No.: 15/435,600

(22) Filed: Feb. 17, 2017

(30) Foreign Application Priority Data
Feb. 29, 2016 (JP) 2016-0036749

(51) Int. Cl. G01L 27/00; C23C 16/455; C23C 16/52; G01L 9/00

(52) U.S. Cl. CPC G01L 27/007; G01L 9/0072; C23C 16/45525; C23C 16/52

(57) ABSTRACT

To enable early detection of abnormal states including accumulation on a pressure sensor, a characteristic measuring portion obtains a change in an output of a pressure sensor in a state in which the temperature of a sensor chip is changed by operation of a temperature controlling portion and thereby obtains a sensor characteristic indicating the change in the output. A state determination portion determines an abnormal state of a diaphragm by comparing the sensor characteristic obtained by the characteristic measuring portion with a reference characteristic, used as a reference, stored in a reference value storing portion.

### CROSS-REFERENCE TO RELATED APPLICATION

The present application claims the benefit of and priority to Japanese Patent Application No. 2016-0036749, filed on Feb. 29, 2016, the entire contents of which are incorporated by reference herein.

### TECHNICAL FIELD

The present invention relates to a pressure sensor state detection method and a pressure sensor state detection system for detecting the state of a pressure reception portion of a capacitance type pressure sensor having a movable portion, such as a diaphragm, functioning as the pressure reception portion.

### BACKGROUND ART

A capacitance type pressure sensor is used in various film formation apparatuses and etching apparatuses using vapor deposition in, for example, manufacturing of a semiconductor device. Examples of a film formation apparatus are a chemical vapor deposition (CVD) apparatus, an atomic layer deposition (ALD) apparatus, and a spatter film formation apparatus. Since such film formation apparatuses accurately control the pressure (degree of vacuum) in a film formation chamber and the partial pressure of a source gas to form a thin film having a thickness of several nanometers, the accurate detection of the pressure is important. In addition, an etching apparatus etches a circuit board to be machined using a corrosive gas having a pressure equal to or less than the atmospheric pressure (mainly 0.01 Pa to several pascals) or plasma including such a corrosive gas. A capacitance type pressure sensor is used to detect such pressure values.

As illustrated in FIG. 5, a pressure sensor includes a base 301 made of an insulating material. A diaphragm 302, which is supported on a base 301 by a supporting portion 301a: is disposed in a movable area 302a apart from the base 301; is made of an insulating material displaceable in the direction of the base 301 in the movable area 302a; and receives a pressure from a measurement target. An airtight chamber 303 is formed between the diaphragm 302 and the base 301 in the movable area 302a.

In addition, the pressure sensor includes a movable electrode 304 formed in the movable area 302a of the diaphragm 302 in the airtight chamber 303 and a fixed electrode 305 on the base 301 so as to face the movable electrode 304 in the airtight chamber 303. In addition, the pressure sensor includes a movable reference electrode 306 formed around the periphery of the movable electrode 304 in the movable area 302a of the diaphragm 302 in the airtight chamber 303 and a fixed reference electrode 307 formed in the part on the base 301 around the periphery of the fixed electrode 305 in the airtight chamber 303 so as to face the movable reference electrode 306.

The pressure sensor configured as described above is mounted in a tank through which a gas (measurement target) flows or a tank containing a measurement target fluid and measures the pressure of the gas. A capacitance type pressure sensor converts the displacement of a diaphragm having received a gas pressure to a capacitance value. Since this pressure sensor does not significantly depend on the gas type, the pressure sensor is widely used for industrial application including a semiconductor device manufacturing facility as described above.

### CITATION LIST

### Patent Literature

[PTL 1] JP-A-06-307964

[PTL 2] JP-T-2010-525324

### SUMMARY

The pressure sensor described above needs to have corrosion resistance against a source gas used for an apparatus for the source gas, or the like, and resistance against by-products generated in a process for film formation, or the like. In addition, since in a film formation process, accumulation occurs on portions through which the source gas flows, such as the inner wall of a film formation chamber, the inner wall of a pipe, the inside of a vacuum pump, and the diaphragm, which is the pressure reception portion of the pressure sensor, various problems are caused (see PTL 1 and PTL 2).

For example, there is the atomic layer deposition (ALD) method that has been developed recently, which has better step coverage and film quality than the chemical vapor deposition (CVD) method generally used conventionally, and which is used to form a gate insulation film, or the like. In the ALD method, the source gas is apt to adhere to various portions through which the source gas flows due to its characteristics, possibly causing unnecessary accumulation, as described above. As illustrated in FIG. 5, sediment 321 is accumulated in the pressure reception area of the diaphragm 302 in the pressure sensor.

In a capacitance type pressure sensor, accumulation on the diaphragm functioning as the pressure reception portion causes the diaphragm to be bent by a stress caused by the sediment, which is unrelated to the pressure to be measured. Although adjustment is made so that the pressure sensor indicates the zero point in the state in which the inside of the processing chamber of the film formation apparatus, which is the measurement target, has been completely vacuum-pumped, the zero point is shifted in the state described above.

In addition, if the thickness of the diaphragm is increased by accumulated sediment, the diaphragm is less bent due to accumulated sediment even under the same pressure, thereby reducing the pressure measurement sensitivity. In addition, when the sediment has viscosity, the motion of the diaphragm in response to a change in the pressure is delayed, thereby causing a delay in the sensor response.

Since the uniformity of the film thickness and quality has been improved recently and an accurate process is needed, the reduction in the pressure detection accuracy becomes problematic. Therefore, to prevent accumulation, the film formation apparatus as described above heats individual portions at, for example, 100 to 200 degrees centigrade, for example, during film formation. However, even when such a workaround including heating is taken, accumulation proceeds bit by bit.

If it is determined that accumulation occurs, for example, zero point shift adjustment is performed. In the zero point shift adjustment or the like, it is necessary to stop the manufacturing process once and vacuum-pump the inside of the apparatus until the inside can be assumed to be a vacuum. It takes a long time to perform this adjustment. In addition, the adjustable range of the zero point shift adjustment has a limitation and, when this limitation is exceeded, it is necessary to remove the pressure sensor from the apparatus and calibrate the pressure sensor again. This calibration needs a special device and is very troublesome.

In addition, when the amount of accumulation on the diaphragm exceeds an acceptable value, the pressure sensor cannot obtain predetermined accuracy and fails. At present, the pressure sensor is replaced, if available, or cleaned based on use history information, such as the number of times the apparatus is used or the cumulative total film thickness. However, the above response based on use history information may not maintain required high pressure detection accuracy.

In addition, reduction in the measurement accuracy of the pressure sensor, as described above, is caused not only by accumulation on the diaphragm, but also by various factors. For example, the pressure sensitivity may be changed by the corrosion or etching deterioration of a diaphragm material that may be caused in the etching process or the cleaning of the chamber. In addition, the stress applied from the housing to the diaphragm may be changed by any reason, possibly changing the sensitivity in response to an applied pressure.

Since calibration, as described above, is necessary to accurately measure the pressure in either case, it is very important to grasp the timing at which calibration is performed. If the sensor is calibrated unnecessarily, the process apparatus needs to be stopped, thereby causing a great waste. Accordingly, an abnormal state of the pressure sensor needs to be detected early.

The invention addresses the above problems with an object of detecting an abnormal state of a pressure sensor early.

A pressure sensor state detection method according to the invention for detecting a state of a pressure reception portion of a pressure sensor detecting displacement of the pressure reception portion as a change in capacitance, the pressure sensor including a sensor chip having the pressure reception portion receiving a pressure from a measurement target, the pressure reception portion being displaceable, the pressure sensor state detection method including a first step for obtaining a change in an output of the pressure sensor in a state in which a temperature of the sensor chip is changed and a second step for determining an abnormal state of the pressure reception portion by comparing a sensor characteristic indicating the change in the output obtained in the first step with a reference characteristic used as a reference.

In the pressure sensor state detection method described above, the abnormal state to be determined in the second step is an accumulation state of sediment on the pressure reception portion. Alternatively, the abnormal state to be determined in the second step may be a state of corrosion or deterioration caused by a chemical reaction between the pressure reception portion and a gas that is the measurement target medium. Alternatively, the abnormal state to be determined in the second step is a state of a change in the pressure sensor output due to a change in a mechanical stress applied to the pressure reception portion.

In the pressure sensor state detection method described above, the sensor characteristic and the reference characteristic represent a relationship between a change in the output and a change in a temperature of the pressure sensor. Alternatively, the sensor characteristic and the reference characteristic represent a time-series change of the output of the pressure sensor.

A pressure sensor state detection system according to the invention includes a pressure sensor detecting displacement of a pressure reception portion as a change in capacitance, the pressure sensor including a sensor chip having the pressure reception portion receiving a pressure from a measurement target, the pressure reception portion being displaceable, a temperature controlling portion changing a temperature of the sensor chip, a characteristic measuring portion obtaining a sensor characteristic indicating a change in an output by obtaining a change in an output of the pressure sensor in a state in which a temperature of the sensor chip is changed by operation of the temperature controlling portion, and a state determination portion determining an abnormal state of the pressure reception portion by comparing a sensor characteristic obtained by the characteristic measuring portion with a reference characteristic used as a reference.

In the pressure sensor state detection system described above, the abnormal state to be determined by the state determination portion is an accumulation state of sediment on the pressure reception portion. Alternatively, the abnormal state to be determined by the state determination portion may be a state of corrosion or deterioration caused by a chemical reaction between the pressure reception portion and a gas that is the measurement target medium. Alternatively, the abnormal state to be determined by the state determination portion may be a state of a change in the pressure sensor output due to a change in a mechanical stress applied to the pressure reception portion.

In the pressure sensor state detection system described above, the sensor characteristic and the reference characteristic represent a relationship between a change in the output and a change in a temperature of the pressure sensor. Alternatively, the sensor characteristic and the reference characteristic represent a time-series change of the output of the pressure sensor.

Because of the reasons described above, according to the invention, it is possible to obtain an excellent effect of detecting an abnormal state, such as sediment, on the pressure sensor early.

### BRIEF DESCRIPTION OF THE DRAWINGS

FIG. 1 is a structural diagram illustrating the structure of a pressure sensor state detection system according to an embodiment of the invention.

FIG. 2 is a flowchart describing a pressure sensor state detection method according to an embodiment of the invention.

FIGS. 3(a), 3(b), and 3(c) are characteristic diagrams illustrating the temperature characteristics of a temperature sensor.

FIGS. 4(a) and 4(b) are characteristic diagrams illustrating time-series changes of a sensor output with respect to temperature changes.

FIG. 5 is a perspective view illustrating the structure of a capacitance type pressure sensor.

### DETAILED DESCRIPTION

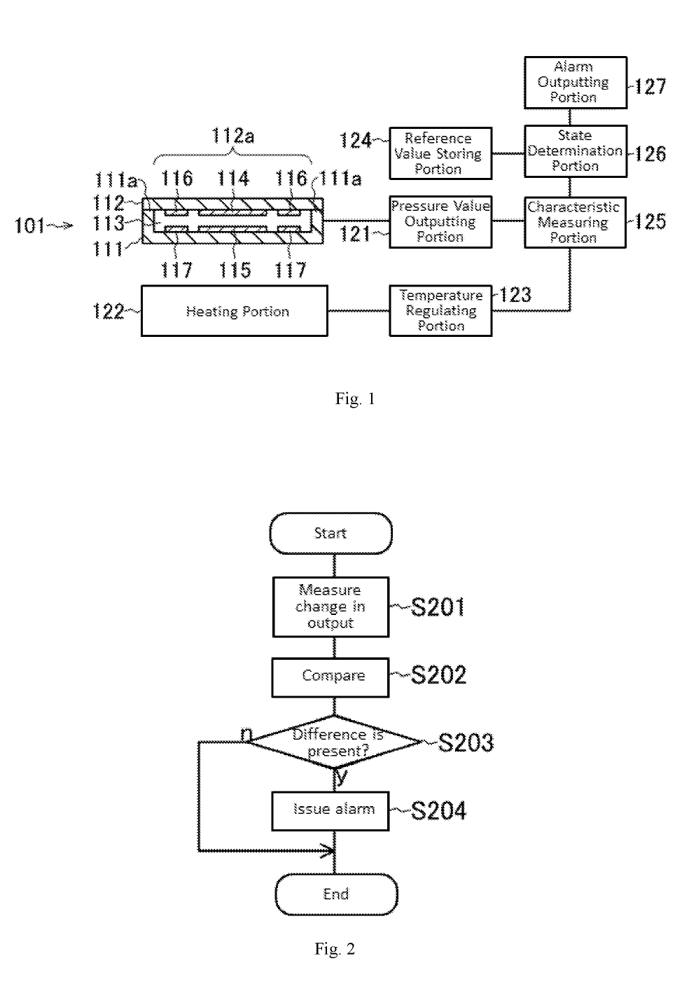

An embodiment of the invention will be described below with reference to the drawings. FIG. 1 is a structural diagram illustrating the structure of a pressure sensor state detection system according to an embodiment of the invention. This system includes a sensor chip 101, a pressure value outputting portion 121, a heating portion 122, a temperature regulating portion 123, a reference value storing portion 124, a characteristic measuring portion 125, a state determination portion 126, and an alarm outputting portion 127.

The sensor chip 101 is of a well-known capacitance type and includes a base 111, a diaphragm 112, a movable electrode 114, and a fixed electrode 115. The base 111 and the diaphragm 112 are made of a heat-resistant and corrosion-resistant insulating material such as, for example, sapphire or alumina ceramic. In addition, the diaphragm 112 functioning as a pressure reception portion is a movable portion supported by a supporting portion 111a of the base 111 and movable in the direction of the base 111 in a movable area 112a inside the supporting portion 111a. The movable area 112a is, for example, circular in plan view.

A sealed airtight chamber 113 is present between the diaphragm 112 and the base 111 in the movable area 112a. When the pressure sensor is used as a vacuum gauge, the inside of the airtight chamber 113 is a vacuum and the airtight chamber 113 is used as a reference vacuum chamber.

In addition, the movable electrode 114 is formed in the movable area 112a of the diaphragm 112 in the airtight chamber 113. In addition, the fixed electrode 115 is formed on the base 111 in the airtight chamber 113 so as to face the movable electrode 114. The sensor chip 101 according to the embodiment includes a movable reference electrode 116 formed around the movable electrode 114 in the movable area 112a of the diaphragm 112 in the airtight chamber 113 and a fixed reference electrode 117 formed on the base 111 around the fixed electrode 115 in the airtight chamber 113 so as to face the movable reference electrode 116.

The pressure value outputting portion 121 converts a change in capacitance to a pressure value using a set sensor sensitivity and outputs the converted value. The pressure sensor is configured by the sensor chip 101 and the pressure value outputting portion 121.

The heating portion 122 is disposed in the vicinity of the sensor chip 101 and changes the temperature of the sensor chip 101 by heating the sensor chip 101 (diaphragm 112) using, for example, resistance heating under control of the temperature regulating portion 123. A temperature controlling portion is configured by the heating portion 122 and the temperature regulating portion 123.

The characteristic measuring portion 125 obtains the sensor characteristic indicating a change in an output by obtaining the change in the output of the pressure sensor (pressure value outputting portion 121) in the state in which the temperature of the sensor chip 101 is changed by operation of the temperature controlling portion. The state determination portion 126 determines an abnormal state of the diaphragm 112 by comparing the sensor characteristic obtained by the characteristic measuring portion 125 with the reference characteristic used as the reference stored in the reference value storing portion 124.

An abnormal state of the diaphragm 112 is, for example, the accumulation state of sediment on the diaphragm 112. Alternatively, the abnormal state of the diaphragm 112 may be the state of corrosion or deterioration caused by a chemical reaction between the diaphragm 112 and a gas that is comprised in a measurement target, such as the measurement target medium. Alternatively, the abnormal state of the diaphragm 112 is the state of a change in the pressure sensor output due to a change in a mechanical stress applied to the diaphragm 112.

The sensor characteristic and the reference characteristic represent the relationship between, for example, a change in the output and a change in a temperature of the pressure sensor. Alternatively, the sensor characteristic and the reference characteristic represent a time-series change of the output of the pressure sensor.

The alarm outputting portion 127 outputs an alarm when the state determination portion 126 determines an abnormality, such as an accumulation of sediment equal to or more than a specified value, on the diaphragm 112. When such an alarm is output, a state in which the pressure sensor needs to be calibrated can be determined.

Next, an operation (pressure sensor state detection method) of the pressure sensor state detection system according to an embodiment of the invention will be described below with reference to the flowchart in FIG. 2.

First, in step S201, the characteristic measuring portion 125 changes the temperature of the sensor chip 101 by operating the heating portion 122 under control of the temperature regulating portion 123 and obtains a change in an output from the pressure value outputting portion 121 in this state.

Next, in step S202, the state determination portion 126 compares a sensor characteristic indicating a change in the output obtained by the characteristic measuring portion 125 with a reference characteristic stored in the reference value storing portion 124. When the difference between the sensor characteristic and the reference characteristic is equal to or more than a threshold as a result of the comparison (y in step S203), the state determination portion 126 determines occurrence of an abnormality, such as accumulation of sediment on the diaphragm 112, and causes the alarm outputting portion 127 to output an alarm in step S204.

The sensor characteristic and the reference characteristic will be described. The case in which sediment is accumulated on a diaphragm functioning as the pressure reception portion will be described below as an example of occurrence of an abnormality. When some substance is accumulated on the diaphragm, there is a difference in material characteristics between the sediment and the diaphragm, so the characteristics of the temperature and the zero point are changed as compared with the case in which no sediment is accumulated. This change also occurs when the diaphragm undergoes corrosion or deterioration by a gas or a mechanical stress applied to the diaphragm. The temperature characteristic indicating changes in the output value with respect to changes in the temperature of the pressure sensor is generated by various factors, such as thermal expansion of the sensor chip itself, the difference in the thermal expansion coefficients between the movable electrode and the diaphragm, the state of welding or bonding between the diaphragm and the base, and effects of a package accommodating the sensor chip. Generally, the temperature characteristic is measured immediately after manufacturing (at the shipment of) the sensor chip and, based on this result, the output of the sensor chip is corrected.

When the reference temperature at which the diaphragm is not deformed (bent) is assumed to be the origin point, a change in capacitance caused when the diaphragm is deformed due to a change in the temperature appears as the temperature characteristic. The pressure sensor is operated by heating it to a predetermined temperature (for example, 150 degrees centigrade) in an actual use state. Accordingly, the sensor chip is generally designed and manufactured so that the diaphragm is not bent at the operating temperature. Accordingly, the operating temperature may be used as the reference temperature.

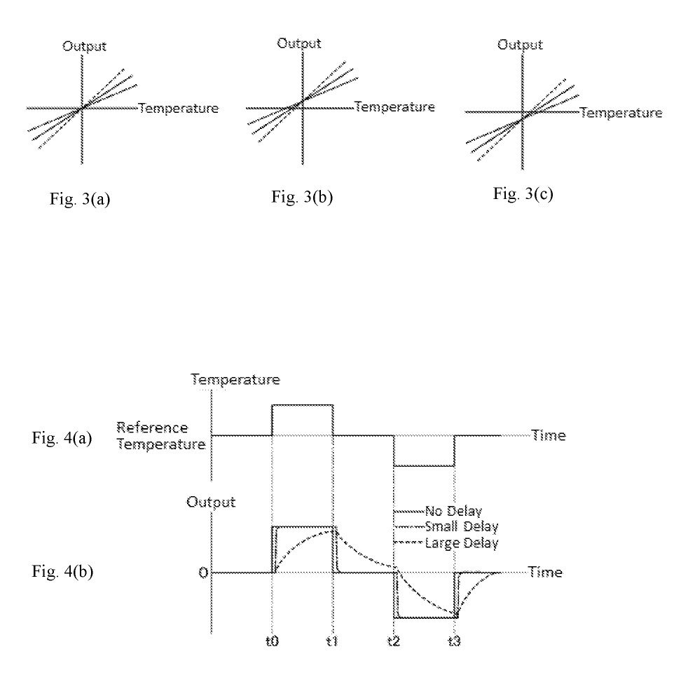

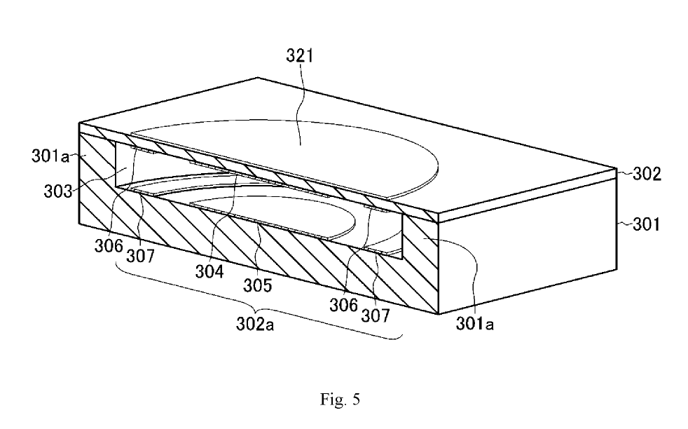

For example, when the change in the temperature is represented on the X axis, the reference temperature is 0, the change in the sensor output due to a change in the capacitance is represented on the Y axis, and the sensor output at the reference temperature is set to 0, the temperature characteristic in the state in which sediment (abnormality) is not present on the diaphragm is approximated as the straight line passing through the origin point in the XY coordinate system. This state is indicated as the straight line in FIG. 3(a).

This temperature characteristic changes when sediment is accumulated on the diaphragm. For example, when the thermal expansion coefficient of sediment is smaller than that of the diaphragm, since a force is applied so as to prevent an original change in the diaphragm in response to a change in the temperature, the inclination of the line indicating the temperature characteristic becomes smaller. This state is indicated by the dot-dash line in FIG. 3(a).

In contrast, when the thermal expansion coefficient of sediment is larger than that of the diaphragm, since a force is applied so as to increase an original change in the diaphragm by a change in the temperature, the inclination of the line indicating the temperature characteristic becomes larger. This state is indicated by the dotted line in FIG. 3(a).

When the zero point shifts in the plus direction, the temperature characteristic changes as illustrated in FIG. 3(b). When the zero point shifts in the minus direction, the temperature characteristic changes as illustrated in FIG. 3(c). In these diagrams, the case in which no accumulation occurs is indicated by a straight line, the case in which the thermal expansion coefficient of sediment is smaller than that of the diaphragm is indicated by a dot-dash line, and the case in which the thermal expansion coefficient of sediment is larger than that of the diaphragm is indicated by a dotted line.

Since the inclinations of these lines are the same if the equivalent of the shift of the zero point is offset, the temperature characteristics in FIGS. 3(b) and 3(c) are the same as the temperature characteristic in FIG. 3(a). As is clear from the description above, the state of sediment on the diaphragm can be determined by the inclination of the temperature characteristic. The temperature characteristic when no sediment is accumulated on the diaphragm, for example, immediately after the sensor chip is manufactured is measured in advance and the temperature characteristic may be used as the reference characteristic.

By comparing the inclination between the reference characteristic and the sensor characteristic, which is the temperature characteristic obtained from the pressure sensor in the actual use state, it is possible to determine the state in which sediment is accumulated on the diaphragm. For example, the sensor characteristic is measured in the state in which sediment is accumulated to the extent to which a problem substantially occurs, the difference between the inclination of the measured sensor characteristic and the inclination of the reference characteristic is obtained, and this difference is set as the threshold. When the difference between the inclination of the sensor characteristic measured in the actual use state and the inclination of the reference characteristic exceeds the threshold, it is determined that sediment has been generated on the diaphragm.

By the way, the change of the temperature characteristic described above becomes apparent when the sediment is relatively hard and the hardness (viscoelasticity) does not significantly change depending on the temperature. In contrast, when the sediment has viscosity and the viscoelasticity changes depending on the temperature, if accumulation is generated on the diaphragm, the time delay of displacement of the diaphragm occurs.

For example, as illustrated in FIG. 4(a), the temperature of the sensor chip is changed on a time-series basis. When no sediment is generated on the diaphragm, no time delay occurs with respect to this temperature change in the sensor output as illustrated by the solid line in FIG. 4(b). In contrast, when a viscous substance is accumulated on the diaphragm, as illustrated by the dot-dash line in FIG. 4(b), a time delay occurs at t1, t2, and t3 in the sensor output after the start time t0. When a very viscous substance is accumulated on the diaphragm, as illustrated by the dotted line in FIG. 4(b), the sensor output may not return to zero even if the temperature is set to the reference temperature in addition to the occurrence of a time delay in the sensor output.

Accordingly, the time-series change in the temperature described above can also be used as the reference characteristic and the sensor characteristic. The time-series change of the sensor output indicated by the solid line in FIG. 4(b) is used as the reference characteristic. In addition, in the state in which sediment is accumulated to the extent to which a problem substantially occurs, the time-series change of the sensor output is measured as the sensor characteristic, and the time delay at certain times (e.g., t2) at which the reference characteristic is set as the reference is set as the threshold. When the time delay from the reference characteristic at time t2 of the sensor characteristic measured in the actual use state exceeds the threshold, it can be determined that accumulation (abnormality) has occurred on the diaphragm.

In addition, the abnormal state of the diaphragm can also be determined by using both the temperature characteristic and the time-series change of the sensor output with respect to temperature change. In this way, various accumulation states can be determined. If it is determined that an abnormality has occurred on the diaphragm in one of the two methods, it is sufficient to output an alarm.

As described above, since the invention determines the abnormal state of the pressure reception portion by comparing the change in the output of the pressure sensor obtained in the state in which the temperature of the sensor chip is changed with the reference characteristic, the abnormal state of the pressure sensor can be detected early. Since the invention can detect (determine) the abnormal state of the pressure sensor while the apparatus having the pressure sensor operates and without removing the pressure sensor from the apparatus, it is possible to grasp the abnormal state quickly even when the inside of the apparatus is in an atmospheric state—in other words, without the need to perform additional work, such as vacuum-pumping until the inside of the apparatus is assumed to be a vacuum.

The invention is not limited to the above embodiment and it is appreciated that those skilled in the art may perform many modifications and combinations within the technical concept of the invention.

DESCRIPTION OF REFERENCE NUMERALS AND SIGNS

101: sensor chip, 111: base, 111a: supporting portion, 112: diaphragm, 112a: movable area, 113: airtight chamber, 114: movable electrode, 115: fixed electrode, 116: movable reference electrode, 117: fixed reference electrode, 121: pressure value outputting portion, 122: heating portion, 123: temperature regulating portion, 124: reference value storing portion, 125: characteristic measuring portion, 126: state determination portion, 127: alarm outputting portion

1. A pressure sensor state detection method for detecting a state of a pressure reception portion of a pressure sensor that detects a displacement of the pressure reception portion as a change in capacitance, the pressure sensor comprising a sensor chip having the pressure reception portion that receives a pressure from a measurement target, the pressure reception portion being displaceable, the pressure sensor state detection method comprising:
obtaining a change in an output of the pressure sensor while changing a temperature of the sensor chip; and
determining an abnormal state of the pressure reception portion by comparing a sensor characteristic indicating the obtained change in the output with a reference characteristic.

2. The pressure sensor state detection method according to claim 1,
wherein the abnormal state to be determined in the determining step is an accumulation state of sediment on the pressure reception portion.

3. The pressure sensor state detection method according to claim 1,
wherein the abnormal state to be determined in the determining step is a state of corrosion or deterioration caused by a chemical reaction between the pressure reception portion and a gas comprised in the measurement target.

4. The pressure sensor state detection method according to claim 1,
wherein the abnormal state to be determined in the determining step is a state of a change in pressure sensor outputs due to a change in a mechanical stress applied to the pressure reception portion.

5. The pressure sensor state detection method according to claim 1,
wherein the sensor characteristic and the reference characteristic represent a relationship between a change in the output and a change in a temperature of the pressure sensor.

6. The pressure sensor state detection method according to claim 1,
wherein the sensor characteristic and the reference characteristic represent a time-series change of the output of the pressure sensor.

7. A pressure sensor state detection system, comprising:
a pressure sensor detecting a displacement of a pressure reception portion as a change in capacitance, the pressure sensor comprising a sensor chip having the pressure reception portion that receives a pressure from a measurement target, the pressure reception portion being displaceable;
a temperature controlling portion changing a temperature of the sensor chip;
a characteristic measuring portion obtaining a sensor characteristic indicating a change in an output by obtaining a change in an output of the pressure sensor while the temperature controlling portion changes the temperature of the sensor chip; and
a state determination portion determining an abnormal state of the pressure reception portion by comparing a sensor characteristic obtained by the characteristic measuring portion with a reference characteristic.

8. The pressure sensor state detection system according to claim 7,
wherein the abnormal state to be determined by the state determination portion is an accumulation state of sediment on the pressure reception portion.

9. The pressure sensor state detection system according to claim 7,
wherein the abnormal state to be determined by the state determination portion is a state of corrosion or deterioration caused by a chemical reaction between the pressure reception portion and a gas comprised in the measurement target.

10. The pressure sensor state detection system according to claim 7,
wherein the abnormal state to be determined by the state determination portion is a state of a change in pressure sensor outputs due to a change in a mechanical stress applied to the pressure reception portion.

11. The pressure sensor state detection system according to claim 7,
wherein the sensor characteristic and the reference characteristic represent a relationship between a change in the output and a change in a temperature of the pressure sensor.

12. The pressure sensor state detection system according to claim 7,
wherein the sensor characteristic and the reference characteristic represent a time-series change of the output of the pressure sensor.
